(19) United States
(12) Patent Application Publication
(10) Pub. No.: US 2019/0056991 A1
(43) Pub. Date: Feb. 21, 2019

(54) ERROR CORRECTION CIRCUIT, OPERATING METHOD THEREOF AND DATA STORAGE DEVICE INCLUDING THE SAME

(71) Applicant: SK hynix Inc., Gyeonggi-do (KR)

(72) Inventor: Jang Seob KIM, Gyeonggi-do (KR)

(21) Appl. No.: 15/908,994

(22) Filed: Mar. 1, 2018

(30) Foreign Application Priority Data
Aug. 18, 2017 (KR) 10-2017-0105025

(51) Int. Cl. G06F 11/10; H03M 13/29

(52) U.S. Cl. CPC G06F 11/1048; G06F 11/1068; H03M 13/2963

(57) ABSTRACT

An error correction circuit includes a control unit suitable for receiving a data chunk including a plurality of data blocks, each of the data blocks being included in a corresponding codeword of a first direction and a corresponding codeword of a second direction; and a decoder suitable for performing a decoding operation for a codeword selected by the control unit in the data chunk, wherein the control unit preferentially selects, depending on a result of a first decoding operation for a first codeword of the first direction, a second codeword of the second direction or a third codeword of the first direction.

### CROSS-REFERENCES TO RELATED APPLICATION

The present application claims priority under 35 U.S.C. § 119(a) to Korean application number 10-2017-0105025, filed on Aug. 18, 2017, which is herein incorporated by reference in its entirety.

### BACKGROUND

### 1. Technical Field

Various embodiments generally relate to an error correction circuit, and, more particularly, to an error correction circuit which is applied to a data storage device.

### 2. Related Art

A data storage device may be configured to store the data provided from an external device, in response to a write request from the external device. Also, the data storage device may be configured to provide stored data to the external device, in response to a read request from the external device. The external device is an electronic device capable of processing data and may include a computer, a digital camera or a mobile phone. The data storage device may operate by being built in the external device, or may operate by being manufactured in a separable form and being coupled to the external device.

A data storage device may include an error correction circuit. The error correction circuit may perform an encoding operation for the data transmitted from an external device, and the data storage device may store the data added with parity data through the encoding operation. Also, when the external device requests stored data, the error correction circuit may perform a decoding operation for stored data, and the data storage device may transmit the data error-corrected through the decoding operation to the external device.

The error correction capability and quick completion of an error correction operation of the error correction circuit may be directly related to the data reliability and operational performance of the data storage device.

### SUMMARY

In an embodiment, an error correction circuit may include: a control unit suitable for receiving a data chunk including a plurality of data blocks, each of the data blocks being included in a corresponding codeword of a first direction and a corresponding codeword of a second direction; and a decoder suitable for performing a decoding operation for a codeword selected by the control unit in the data chunk, wherein the control unit preferentially selects, depending on a result of a first decoding operation for a first codeword of the first direction, a second codeword of the second direction or a third codeword of the first direction.

In an embodiment, a method for operating an error correction circuit may include: receiving a data chunk including a plurality of data blocks, each of the data blocks being included in a corresponding codeword of a first direction and a corresponding codeword of a second direction; preferentially selecting, depending on a result of a first decoding operation for a first codeword of the first direction, a second codeword of the second direction or a third codeword of the first direction; and performing a decoding operation for a selected codeword.

In an embodiment, a data storage device may include: a nonvolatile memory device suitable for reading and outputting a data chunk including a plurality of data blocks, each of the data blocks being included in a corresponding codeword of a first direction and a corresponding codeword of a second direction; and an error correction circuit suitable for performing an error correction operation for the data chunk, the error correction circuit including a control unit suitable for preferentially selecting, depending on a result of a first decoding operation for a first codeword of the first direction, a second codeword of the second direction or a third codeword of the first direction; and a decoder suitable for performing a decoding operation for a codeword selected by the control unit.

In an embodiment, an error-correction method may include: performing first iterations of an error-correction operation for respective first-direction codewords in an array of codewords formed by data blocks; and selectively performing a second iteration of the error-correction operation for a second-direction codeword in the array, wherein the second iteration follows a previous first iteration of success, and wherein the second codeword includes one or more data blocks error-corrected by the previous first iteration of success.

### BRIEF DESCRIPTION OF THE DRAWINGS

The above and other features and advantages of the present invention will become more apparent to those skilled in the art to which the present invention belongs by describing various embodiments thereof with reference to the attached drawings in which:

FIG. 1 is a block diagram illustrating an example of an error correction circuit in accordance with an embodiment.

FIG. 2 is a diagram illustrating an example of a data chunk based on a TPC algorithm.

FIGS. 3A and 3B are examples of diagrams to assist in the description of a method for the error correction circuit of FIG. 1 to perform an error correction operation for a data chunk.

FIG. 4 is an example of a flow chart to assist in the description of a method for operating the error correction circuit of FIG. 1.

FIG. 5 is a block diagram illustrating an example of a data storage device in accordance with an embodiment.

FIG. 6 is a block diagram illustrating an example of a solid state drive (SSD) in accordance with an embodiment.

FIG. 7 is a block diagram illustrating an example of a data processing system in accordance with an embodiment.

### DETAILED DESCRIPTION

Hereinafter, an error correction circuit, an operating method thereof and a data storage device including the same according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology used is for describing particular embodiments only and is not intended to limit the scope of the present invention.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The phrase “at least one of . . . and . . . ,” when used herein with a list of items, means a single item from the list or any combination of items in the list. For example, “at least one of A, B, and C” means, only A, or only B, or only C, or any combination of A, B, and C.

The term “or” as used herein means either one of two or more alternatives but not both nor any combinations thereof.

As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, an element also referred to as a feature described in connection with one embodiment may be used singly or in combination with other elements of another embodiment, unless specifically indicated otherwise.

Hereinafter, the various embodiments of the present invention will be described in detail with reference to the attached drawings.

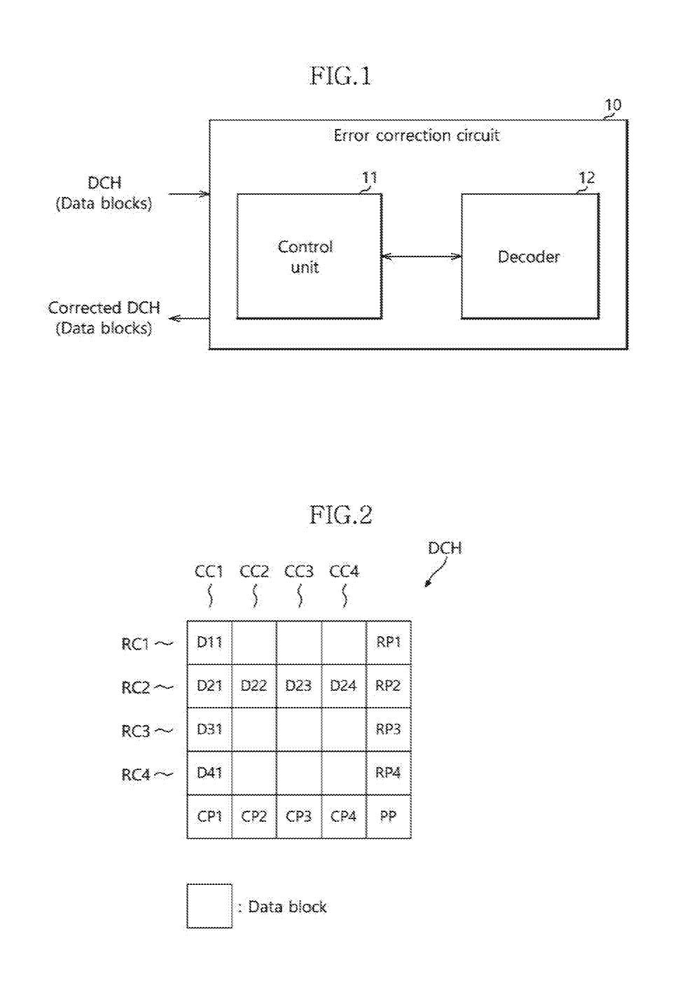

FIG. 1 is a block diagram illustrating an example of an error correction circuit 10 in accordance with an embodiment.

The error correction circuit 10 may receive a data chunk DCH, perform an error correction operation for the data chunk DCH, and output a corrected data chunk CORRECTED DCH.

The data chunk DCH may be data generated based on a turbo product code (TPC) algorithm. The data chunk DCH may include a plurality of data blocks, and each of the data blocks may be included in a corresponding codeword of a first direction and a corresponding codeword of a second direction. The first direction and the second direction may be a row direction and a column direction or vice versa. Therefore, the data chunk DCH may include codewords of the row direction, that is, row codewords, and codewords of the column direction, that is, column codewords. The structure of the data chunk DCH will be described in detail with reference to FIG. 2.

The error correction circuit 10 may include a control unit 11 and a decoder 12.

The control unit 11 may select a codeword for which a decoding operation is to be performed at the current iteration of the decoding operation, in the data chunk DCH, and may provide the selected codeword to the decoder 12. The control unit 11 may control the decoder 12 to perform a decoding operation for a codeword having a high possibility of success in the decoding operation.

In detail, the control unit 11 may preferentially select, depending on a result of a decoding operation for a codeword of the first direction at the previous iteration of the decoding operation, a codeword of the second direction or another codeword of the first direction such that a decoding operation is successively performed for the codeword of the second direction or another codeword of the first direction at the current iteration of the decoding operation. That is, depending on a result of the previous iteration of the decoding operation, the control unit 11 may retain or change the direction of a codeword at the current iteration of the decoding operation.

When the decoding operation for the codeword of the first direction succeeds at the previous iteration of the decoding operation, the control unit 11 may preferentially select a codeword of the second direction at the current iteration of the decoding operation. When the decoding operation for the codeword of the first direction succeeds at the previous iteration of the decoding operation, the control unit 11 may change the direction of a codeword at the current iteration of the decoding operation. In particular, for the current iteration of the decoding operation, the control unit 11 may identify a data block corrected in the codeword at the previous iteration of the decoding operation, and may preferentially select a codeword of the second direction which includes the corrected data block at the current iteration of the decoding operation. When a plurality of data blocks are corrected at the previous iteration of the decoding operation, the control unit 11 may sequentially select a plurality of codewords of the second direction which include the corrected data blocks at the current iteration of the decoding operation.

Furthermore, when the decoding operation for the codeword of the first direction fails at the previous iteration of the decoding operation, the control unit 11 may preferentially select another codeword of the first direction at the current iteration of the decoding operation. Namely, when the decoding operation for the codeword of the first direction fails at the previous iteration of the decoding operation, the control unit 11 may retain the direction of a codeword at the current iteration of the decoding operation.

The decoder 12 may perform a decoding operation for a codeword selected by the control unit 11. The decoder 12 may notify the control unit 11 of whether the decoding operation is a success or a failure at the current iteration of the decoding operation. While the decoder 12 may perform a decoding operation for a codeword based on, for example, a BCH algorithm, it is to be noted that the embodiment is not limited thereto.

According to an embodiment, the control unit 11 may perform a pre-decoding process for the data chunk DCH. In the pre-decoding process, the decoder 12 may perform a decoding operation for each of the codewords included in the data chunk DCH according to control of the control unit 11. While the decoding operation for each of the codewords may be performed based on, for example, a BCH algorithm, it is to be noted that the embodiment is not limited thereto. The decoder 12 may successfully complete the error correction operation for the data chunk DCH through the pre-decoding process or may fail in decoding operations for some codewords of the data chunk DCH.

When the control unit 11 performs the pre-decoding process, the above-described decoding process may be termed as a post-decoding process to be distinguished from the pre-decoding process. The control unit 11 may perform the post-decoding process for codewords for which decoding operations have failed in the pre-decoding process. The control unit 11 may quickly complete the error correction operation by controlling for a codeword of which direction the post-decoding process is to be preferentially performed.

Summarizing these, the error correction circuit 10 according to the present embodiment may select a codeword for which a decoding operation is to be performed in the data chunk DCH, not according to a simple order as arranged in the data chunk DCH but according to the success possibility of the decoding operation. Therefore, the error correction circuit 10 may quickly complete the error correction operation for the data chunk DCH.

FIG. 2 is a diagram illustrating an example of a data chunk DCH based on a TPC algorithm.

Referring to FIG. 2, the data chunk DCH generated based on the TPC algorithm may include a plurality of data blocks. While not shown, each of the data blocks may include a plurality of data bits. The data blocks may be combined to configure row codewords RC1 to RC4 and column codewords CC1 to CC4. A certain one data block may be included in a certain one row codeword and at the same time may be included in a certain one column codeword. Codewords of a row direction may mean the row codewords RC1 to RC4, and codewords of a column direction may mean the column codewords CC1 to CC4. While FIG. 2 illustrates the data chunk DCH which is configured by the four row codewords RC1 to RC4 and the four column codewords CC1 to CC4, it is to be noted that the numbers of row codewords and column codewords included in the data chunk DCH are not limited thereto.

The row codewords RC1 to RC4 may include row parity data blocks RP1 to RP4. Each of the row codewords RC1 to RC4 may include a row parity data block which is generated as corresponding data blocks are encoded. For example, the row codeword RC2 may include the row parity data block RP2 which is generated as data blocks D21 to D24 are encoded. While an encoding operation may be performed based on, for example, a BCH algorithm, to generate each of the row parity data blocks RP1 to RP4, it is to be noted that an encoding operation is not limited thereto in the present embodiment and may be performed based on various ECC algorithms.

The column codewords CC1 to CC4 may include column parity data blocks CP1 to CP4. Each of the column codewords CC1 to CC4 may include a column parity data block which is generated as corresponding data blocks are encoded. For example, the column codeword CC1 may include the column parity data block CP1 which is generated as data blocks D11 to D41 are encoded. While an encoding operation may be performed based on, for example, a BCH algorithm, to generate each of the column parity data blocks CP1 to CP4, it is to be noted that an encoding operation is not limited thereto in the present embodiment and may be performed based on various ECC algorithms.

The data chunk DCH may further include an additional parity data block PP. The additional parity data block PP may be generated as the row parity data blocks RP1 to RP4 and the column parity data blocks CP1 to CP4 are encoded. The additional parity data block PP may be used to correct an error which occurred in the row parity data blocks RP1 to RP4 and the column parity data blocks CP1 to CP4.

The decoder 12 may perform decoding operations for the row codewords RC1 to RC4, based on the row parity data blocks RP1 to RP4. In detail, a decoding operation may be performed for each of the row codewords RC1 to RC4 by correcting errors included in corresponding data blocks, based on a corresponding row parity data block. For example, a decoding operation for the row codeword RC2 may be performed by correcting errors included in the data blocks D21 to D24, based on the row parity data block RP2.

Similarly, the decoder 12 may perform decoding operations for the column codewords CC1 to CC4, based on the column parity data blocks CP1 to CP4. In detail, a decoding operation may be performed for each of the column codewords CC1 to CC4 by correcting errors included in corresponding data blocks, based on a corresponding column parity data block. For example, a decoding operation for the column codeword CC1 may be performed by correcting errors included in the data blocks D11 to D41, based on the column parity data block CP1.

In the data chunk DCH, errors included in the same data block may be corrected through a decoding operation for a corresponding row codeword or a decoding operation for a corresponding column codeword. Therefore, errors included in the same data block may be corrected through a decoding operation for a corresponding column codeword at the current iteration of the decoding operation even though they are not corrected through a decoding operation for a corresponding row codeword at the previous iteration of the decoding operation, or vice versa.

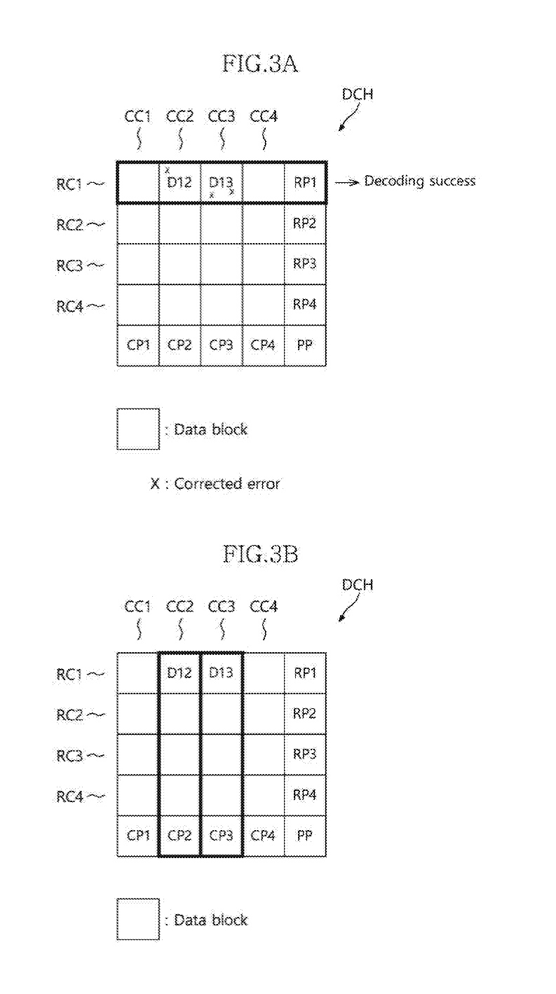

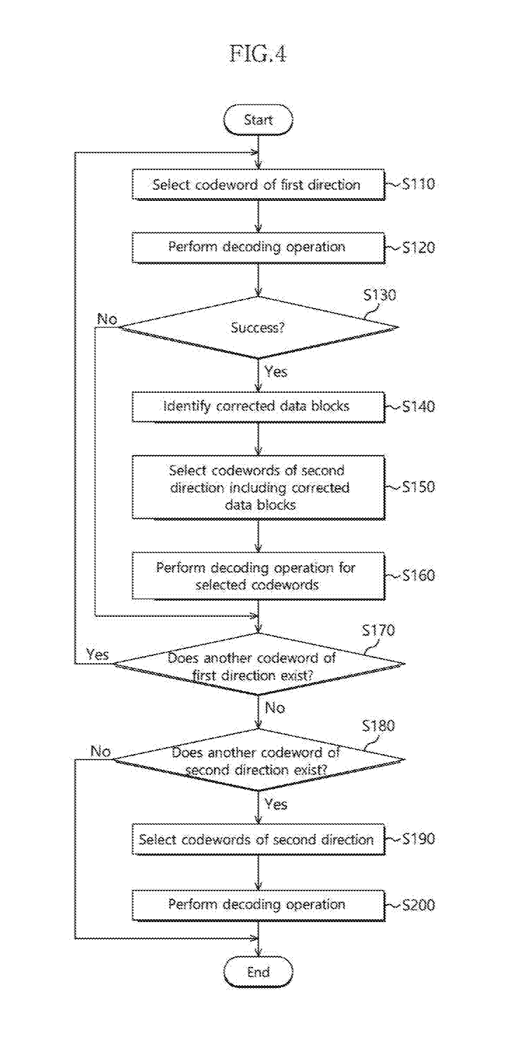

FIGS. 3A and 3B are examples of diagrams to assist in the description of a method for the error correction circuit 10 of FIG. 1 to perform an error correction operation for a data chunk DCH.

Referring to FIG. 3A, the control unit 11 may select, for example, a row codeword RC1 in the data chunk DCH, and the decoder 12 may perform a decoding operation for the row codeword RC1. When the decoding operation for the row codeword RC1 succeeds at the previous iteration of the decoding operation, the control unit 11 may identify corrected data blocks D12 and D13 in the row codeword RC1.

For example, for the current iteration of the decoding operation the control unit 11 may identify the corrected data blocks D12 and D13 by comparing the row codewords RC1 before and after the previous iteration of the decoding operation is performed. For example, at the previous iteration of the decoding operation, one error may have been corrected in the data block D12, and, for example, two errors may have been corrected in the data block D13.

Referring to FIG. 3B, the control unit 11 may select column codewords CC2 and CC3 including the corrected data blocks D12 and D13 for the current iteration of the decoding operation. Since some errors of the column codewords CC2 and CC3 are corrected through the decoding operation for the row codeword RC1 at the previous iteration of the decoding operation, the possibilities of decoding operations for the column codewords CC2 and CC3 to succeed may increase at the current iteration of the decoding operation. Therefore, the control unit 11 may sequentially select the column codewords CC2 and CC3 such that the decoding operations for the respective column codewords CC2 and CC3 may be performed preferentially to the other codewords at the current iteration of the decoding operation.

Furthermore, the correction rates of the corrected data blocks D12 and D13 at the previous iteration of the decoding operation may be considered. A correction rate may mean how many errors are corrected in a corresponding corrected data block. The correction rate may be determined based on the number of corrected errors in the corresponding corrected data block at the previous iteration of the decoding operation. For example, the correction rate of the column codeword CC3 in which two errors are corrected may be higher than the correction rate of the column codeword CC2 in which one error is corrected at the previous iteration of the decoding operation.

According to an embodiment, the control unit 11 may preferentially select only a part of the column codewords CC2 and CC3 at the current iteration of the decoding operation based on the correction rates of the corrected data blocks D12 and D13 of the previous iteration of the decoding operation. For example, only when the correction rate of the data block D13 exceeds a predetermined reference between the corrected data blocks D12 and D13 of the previous iteration of the decoding operation, the control unit 11 may preferentially select only the column codeword CC3 for the current iteration of the decoding operation between the column codewords CC2 and CC3.

Unlike the illustration of FIG. 3A, when the decoding operation for the row codeword RC1 fails at the previous iteration of the decoding operation, the control unit 11 may continuously select another codeword of a row direction, for example, a row codeword RC2 for the current iteration of the decoding operation. When the decoding operation for the row codeword RC1 fails at the previous iteration of the decoding operation, the control unit 11 may retain the direction of a codeword as the row direction for the current iteration of the decoding operation.

FIGS. 3A and 3B show a procedure in which a codeword of a column direction is preferentially selected for the current iteration of the decoding operation depending on a success/failure result of a decoding operation of the row direction at the previous iteration of the decoding operation. Similar to this, a codeword of the row direction may be preferentially selected for the current iteration of the decoding operation depending on a success/failure result of a decoding operation of the column direction at the previous iteration of the decoding operation. For example, in FIG. 3B, when a decoding operation for the column codeword CC3 succeeds at the previous iteration of the decoding operation, a corrected data block may be identified in the column codeword CC3, and a codeword of the row direction which includes the corrected data block may be preferentially selected for the current iteration of the decoding operation.

According to an embodiment, after decoding operations for the respective column codewords CC2 and CC3 are performed at the previous iteration of the decoding operation in FIG. 3B, the control unit 11 may preferentially select a codeword of the row direction, for example, the row codeword RC2 for the current iteration of the decoding operation, regardless of success/failure results of the decoding operations for the column codewords CC2 and CC3 at the current iteration of the decoding operation. That is, when a codeword of the column direction is selected for the current iteration of the decoding operation depending on a success/failure result of a decoding operation for a codeword of the row direction at the previous iteration of the decoding operation, a codeword of the row direction may be selected for the current iteration of the decoding operation independently of a success/failure result of the decoding operation for the codeword of the column direction at the previous iteration of the decoding operation, for example, according to a predetermined order.

Similarly, according to an embodiment, even though a codeword of the row direction is selected for the current iteration of the decoding operation depending on a success/failure result of a decoding operation of the column direction at the previous iteration of the decoding operation, a codeword of the column direction may be selected for the current iteration of the decoding operation regardless of a success/failure result of the decoding operation of the row direction at the previous iteration of the decoding operation.

FIG. 4 is an example of a flow chart to assist in the description of a method for operating the error correction circuit 10 of FIG. 1. FIG. 4 shows a method in which the error correction circuit 10 selects a codeword for the current iteration of the decoding operation in the same direction or a different direction, and performs the current iteration of the decoding operation depending on a result of the previous iteration of the decoding operation for the data chunk DCH. In the method shown in FIG. 4, a first direction and a second direction may be a row direction and a column direction or vice versa.

Referring to FIG. 4, at step S110, the control unit 11 may select a codeword of the first direction.

At step S120, the decoder 12 may perform a first iteration of a decoding operation for the selected codeword of the first direction. The decoder 12 may notify the control unit 11 of the result of the decoding operation.

At step S130, the control unit 11 may determine whether the first iteration of the decoding operation for the codeword of the first direction has succeeded. When it is determined that the first iteration of the decoding operation has failed, the process may proceed to step S170. However, when it is determined that the first iteration of the decoding operation has succeeded, the process may proceed to step S140.

At the step S140, the control unit 11 may identify one or more corrected data blocks in the codeword of the first direction at the first iteration of the decoding operation.

At step S150, for a second iteration of the decoding operation, the control unit 11 may select one or more codewords of the second direction which include the corrected data blocks at the first iteration of the decoding operation.

At step S160, the decoder 12 may perform the second iteration of the decoding operation for each of the selected codewords of the second direction. The decoder 12 may notify the control unit 11 of the result of the second iteration of the decoding operation.

At the step S170, the control unit 11 may determine whether a remaining codeword of the first direction for which a third iteration of the decoding operation is to be performed exists in the data chunk DCH. When a remaining codeword of the first direction for the third iteration of the decoding operation exists, the process may proceed to the step S110. That is, at the step S110, the control unit 11 may select one among the remaining codewords of the first direction for which a third iteration of the decoding operation is to be performed after the first and second iterations of the decoding operation.

However, at the step S170, when any remaining codeword of the first direction for which the third iteration of the decoding operation to be performed does not exist, the process may proceed to step S180.

At the step S180, the control unit 11 may determine whether a remaining codeword of the second direction for which a fourth iteration of the decoding operation is to be performed exists in the data chunk DCH. When a remaining codeword of the second direction does not exist, the process may be ended. However, at the step S180, when a remaining codeword of the second direction for which the fourth iteration of the decoding operation is to be performed exists, the process may proceed to step S190.

At the step S190, the control unit 11 may select one among remaining codewords of the second direction for which the fourth iteration of the decoding operations are to be performed.

At step S200, the decoder 12 may perform the fourth iteration of the decoding operation for each of the selected codewords of the second direction. The decoder 12 may notify the control unit 11 of the result of the fourth iteration of the decoding operation.

According to an embodiment, after completion of the step S200, the control unit 11 may repeat whole steps S110 to S200 for codewords for which the first to fourth iterations of the decoding operations have failed.

As to step S170 of FIG. 4, a codeword of the first direction may be selected for the third iteration of the decoding operation regardless of a success/failure result of a decoding operation of the second direction at the second iteration of the decoding operation. However, as described above, a codeword including a corrected data block at the second iteration of the decoding operation among the remaining codewords of the first direction may be selected for the third iteration of the decoding operation depending on a success/failure result of the second iteration of the decoding operation of the second direction.

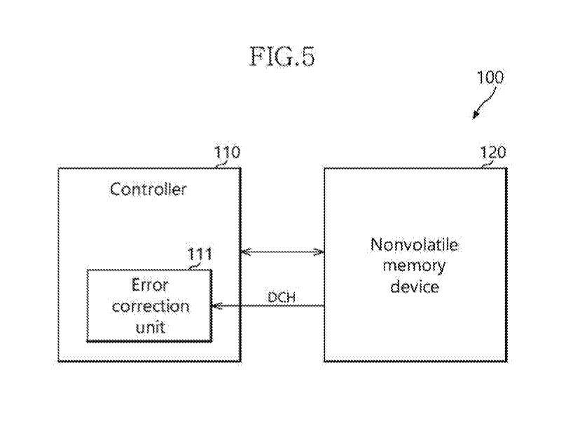

FIG. 5 is a block diagram illustrating an example of a data storage device 100 in accordance with an embodiment.

The data storage device 100 may be configured to store data provided from an external device, in response to a write request from the external device. Also, the data storage device 100 may be configured to provide stored data to the external device, in response to a read request from the external device.

The data storage device 100 may be configured by a Personal Computer Memory Card International Association (PCMCIA) card, a Compact Flash (CF) card, a smart media card, a memory stick, various multimedia cards (MMC, eMMC, RS-MMC, and MMC-Micro), various secure digital cards (SD, Mini-SD, and Micro-SD), a Universal Flash Storage (UFS), a Solid State Drive (SSD) and the like.

The data storage device 100 may include a controller 110 and a nonvolatile memory device 120.

The controller 110 may control general operations of the data storage device 100. The controller 110 may store data in the nonvolatile memory device 120 in response to a write request transmitted from the external device, and may read data stored in the nonvolatile memory device 120 and output read data to the external device in response to a read request transmitted from the external device.

The controller 110 may include an error correction unit 111. The error correction unit 111 may be configured in substantially the same manner as the error correction circuit 10 of FIG. 1. The error correction unit 111 may perform an error correction operation as described above with reference to FIGS. 1 to 4, for a data chunk DCH read from the nonvolatile memory device 120.

The nonvolatile memory device 120 may store the data transmitted from the controller 110 and may read out stored data and transmit the read-out data to the controller 110, according to the control of the controller 110.

The nonvolatile memory device 120 may include a flash memory, such as a NAND flash or a NOR flash, a Ferroelectrics Random Access Memory (FeRAM), a Phase-Change Random Access Memory (PCRAM), a Magnetoresistive Random Access Memory (MRAM), a Resistive Random Access Memory (ReRAM), and the like.

While it is illustrated in FIG. 5 that the data storage device 100 includes one nonvolatile memory device 120, it is to be noted that the number of nonvolatile memory devices included in the data storage device 100 is not limited thereto.

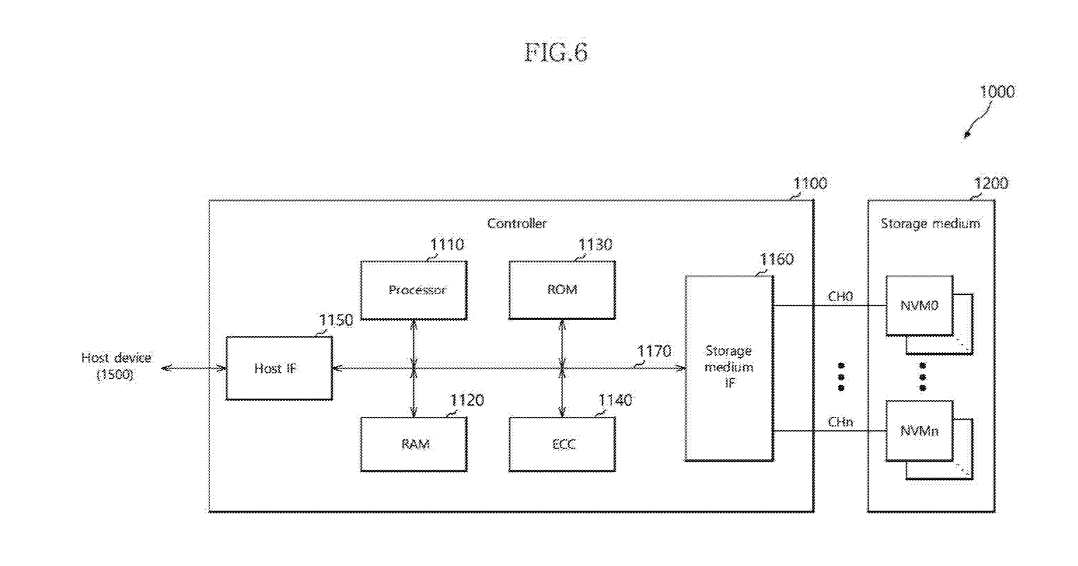

FIG. 6 is a block diagram illustrating an example of a solid state drive (SSD) 1000 in accordance with an embodiment.

The SSD 1000 may include a controller 1100 and a storage medium 1200.

The controller 1100 may control data exchange between a host device 1500 and the storage medium 1200. The controller 1100 may include a processor 1110, a RAM 1120, a ROM 1130, an ECC unit 1140, a host interface 1150 and a storage medium interface 1160 which are coupled through an internal bus 1170.

The processor 1110 may control general operations of the controller 1100. The processor 1110 may store data in the storage medium 1200 and read stored data from the storage medium 1200, according to data processing requests from the host device 1500. In order to efficiently manage the storage medium 1200, the processor 1110 may control internal operations of the SSD 1000 such as a merge operation, a wear leveling operation, and so forth.

The RAM 1120 may store programs and program data to be used by the processor 1110. The RAM 1120 may temporarily store data transmitted from the host interface 1150 before transferring it to the storage medium 1200, and may temporarily store data transmitted from the storage medium 1200 before transferring it to the host device 1500.

The ROM 1130 may store program codes to be read by the processor 1110. The program codes may include commands to be processed by the processor 1110, for the processor 1110 to control the internal units of the controller 1100.

The ECC unit 1140 may encode data to be stored in the storage medium 1200, and may decode data read from the storage medium 1200. The ECC unit 1140 may detect and correct an error which occurred in data, according to an ECC algorithm. The ECC unit 1140 may be configured in substantially the same manner as the error correction circuit 10 of FIG. 1.

The host interface 1150 may exchange data processing requests, data, etc. with the host device 1500.

The storage medium interface 1160 may transmit control signals and data to the storage medium 1200. The storage medium interface 1160 may be transmitted with data from the storage medium 1200. The storage medium interface 1160 may be coupled with the storage medium 1200 through a plurality of channels CHO to CHn.

The storage medium 1200 may include a plurality of nonvolatile memory devices NVM0 to NVMn. Each of the plurality of nonvolatile memory devices NVM0 to NVMn may perform a write operation and a read operation according to control of the controller 1100.

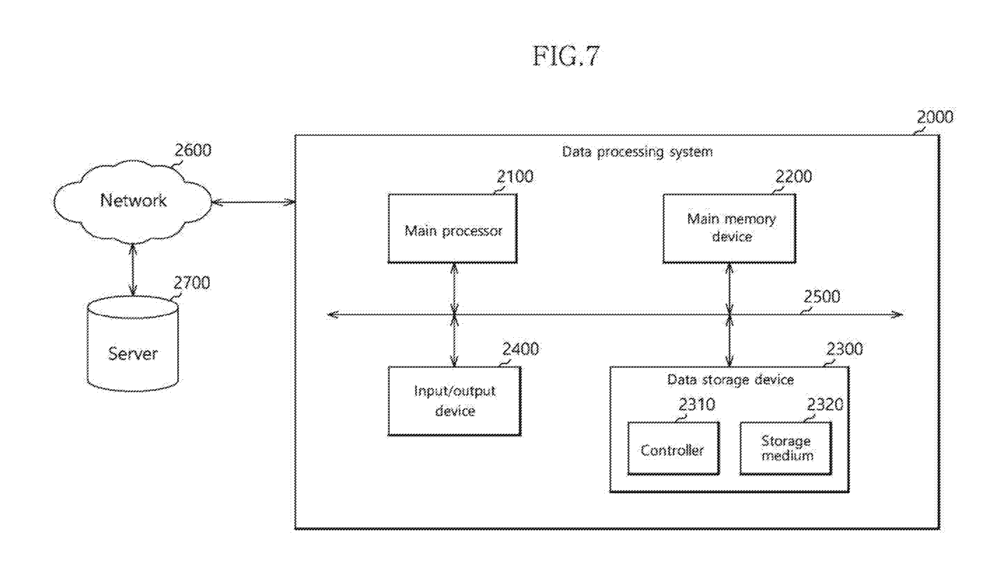

FIG. 7 is a block diagram illustrating a representation of an example of a data processing system 2000 in accordance with an embodiment.

The data processing system 2000 may include a computer, a laptop, a netbook, a smart phone, a digital TV, a digital camera, a navigator, etc. The data processing system 2000 may include a main processor 2100, a main memory device 2200, a data storage device 2300, and an input/output device 2400. The internal units of the data processing system 2000 may exchange data, control signals, etc. through a system bus 2500.

The main processor 2100 may control general operations of the data processing system 2000. The main processor 2100 may be a central processing unit, for example, such as a microprocessor. The main processor 2100 may execute software such as an operation system, an application, a device driver, and so forth, on the main memory device 2200.

The main memory device 2200 may store programs and program data to be used by the main processor 2100. The main memory device 2200 may temporarily store data to be transmitted to the data storage device 2300 and the input/output device 2400.

The data storage device 2300 may include a controller 2310 and a storage medium 2320. The data storage device 2300 may be configured and operate substantially similarly to the data storage device 100 of FIG. 5 or the SSD 1000 of FIG. 6.

The input/output device 2400 may include a keyboard, a scanner, a touch screen, a screen monitor, a printer, a mouse, or the like, capable of exchanging data with a user, such as receiving a command for controlling the data processing system 2000 from the user or providing a processed result to the user.

According to an embodiment, the data processing system 2000 may communicate with at least one server 2700 through a network 2600 such as a LAN (local area network), a WAN (wide area network), a wireless network, and so on. The data processing system 2000 may include a network interface (not shown) to access the network 2600.

While various embodiments have been described above, it will be understood to those skilled in the art that the embodiments described are examples only. Accordingly, the error correction circuit, the operating method thereof and the data storage device including the same described herein should not be limited based on the described embodiments.

What is claimed is:

1. An error correction circuit comprising:
a control unit suitable for receiving a data chunk including a plurality of data blocks, each of the data blocks being included in a corresponding codeword of a first direction and a corresponding codeword of a second direction; and
a decoder suitable for performing a decoding operation for a codeword selected by the control unit in the data chunk,
wherein the control unit selects, depending on a result of a first decoding operation for a first codeword of the first direction, a second codeword of the second direction or a third codeword of the first direction.

2. The error correction circuit according to claim 1, wherein, when the first decoding operation succeeds, the control unit identifies one or more corrected data blocks in the first codeword, and selects each of codewords of the second direction including the corrected data blocks, as the second codeword.

3. The error correction circuit according to claim 2, wherein the control unit selects the third codeword after selecting the codewords of the second direction.

4. The error correction circuit according to claim 2, wherein the control unit identifies one or more data blocks having correction rates that exceed a predetermined reference, among the corrected data blocks, and selects each of codewords of the second direction including the identified data blocks, as the second codeword.

5. The error correction circuit according to claim 1, wherein the control unit selects the third codeword when the first decoding operation fails.

6. The error correction circuit according to claim 1,
wherein the decoder performs a pre-decoding process for the data chunk before performing the first decoding operation, and
wherein the first codeword, the second codeword and the third codeword are codewords for which decoding operations in the pre-decoding process have failed.

7. A method for operating an error correction circuit, comprising:
receiving a data chunk including a plurality of data blocks, each of the data blocks being included in a corresponding codeword of a first direction and a corresponding codeword of a second direction;
selecting, depending on a result of a first decoding operation for a first codeword of the first direction, a second codeword of the second direction or a third codeword of the first direction; and
performing a decoding operation for a selected codeword.

8. The method according to claim 7, wherein the selecting of the second codeword or the third codeword comprises:
identifying one or more corrected data blocks in the first codeword when the first decoding operation succeeds; and
selecting each of codewords of the second direction including the corrected data blocks, as the second codeword.

9. The method according to claim 8, wherein the selecting of the second codeword or the third codeword further comprises:
selecting the third codeword after selecting each of the codewords of the second direction.

10. The method according to claim 8, wherein the selecting of the second codeword or the third codeword comprises:
identifying one or more data blocks having correction rates that exceed a predetermined reference, among the corrected data blocks; and
selecting each of codewords of the second direction including the identified data blocks, as the second codeword.

11. The method according to claim 7, wherein the selecting of the second codeword or the third codeword comprises:
selecting the third codeword when the first decoding operation fails.

12. The method according to claim 7, further comprising:
performing a pre-decoding process for the data chunk before performing the first decoding operation,
wherein the first codeword, the second codeword and the third codeword are codewords for which decoding operations in the pre-decoding process have failed.

13. A data storage device comprising:
a nonvolatile memory device suitable for reading and outputting a data chunk including a plurality of data blocks, each of the data blocks being included in a corresponding codeword of a first direction and a corresponding codeword of a second direction; and
an error correction circuit suitable for performing an error correction operation for the data chunk,
the error correction circuit comprising
a control unit suitable for selecting, depending on a result of a first decoding operation for a first codeword of the first direction, a second codeword of the second direction or a third codeword of the first direction; and
a decoder suitable for performing a decoding operation for a codeword selected by the control unit.

14. The data storage device according to claim 13, wherein, when the first decoding operation succeeds, the control unit identifies one or more corrected data blocks in the first codeword, and selects each of codewords of the second direction including the corrected data blocks, as the second codeword.

15. The data storage device according to claim 14, wherein the control unit selects the third codeword after selecting the codewords of the second direction.

16. The data storage device according to claim 14, wherein the control unit identifies one or more data blocks having correction rates that exceed a predetermined reference, among the corrected data blocks, and selects each of codewords of the second direction including the identified data blocks, as the second codeword.

17. The data storage device according to claim 13, wherein the control unit selects the third codeword when the first decoding operation fails.

18. The data storage device according to claim 13,
wherein the decoder performs a pre-decoding process for the data chunk before performing the first decoding operation, and
wherein the first codeword, the second codeword and the third codeword are codewords for which decoding operations in the pre-decoding process have failed.
